(19) United States
(12) Patent Application Publication
(10) Pub. No.: US 2013/0187254 A1
(43) Pub. Date: Jul. 25, 2013

(54) Semiconductor Chip and Methods for Producing the Same

(71) Applicants: Peking University Founder Group Co., Ltd., Beijing (CN); Founder Microelectronics International Co., Ltd., Shenzhen (CN)

(72) Inventor: Wanli MA, Beijing (CN)

(73) Assignees: FOUNDER MICROELECTRONICS INTERNATIONAL CO., LTD., Shenzhen (CN); PEKING UNIVERSITY FOUNDER GROUP CO., LTD., Beijing (CN)

(21) Appl. No.: 13/730,361

(22) Filed: Dec. 28, 2012

(30) Foreign Application Priority Data
Dec. 28, 2011 (CN) 201110448915.5

(51) Int. Cl. H01L 21/768; H01L 23/62

(52) U.S. Cl. CPC H01L 21/76883; H01L 23/62
USPC 257/529; 438/601

(57) ABSTRACT

A fabrication method for thickening pad metal layers comprises: growing a first metal layer on a silicon substrate; etching the first metal layer to obtain a metal wire comprising a metal fuse and a pad; growing a passivation layer on the metal wire; etching the passivation layer to obtain a first window to expose a pad area; growing a second metal layer on the passivation layer having the first window; etching the second metal layer to obtain a metal layer covering the pad area only and expose the passivation layer outside the pad area; and etching the passivation layer outside the pad area to obtain a second window to expose a metal fuse area.

### FIELD OF THE INVENTION

The present invention relates to a technical field of a semiconductor chip fabrication process, and more particularly to a semiconductor chip and a fabrication method for thickening pad metal layers thereof.

### BACKGROUND OF THE INVENTION

In a fabrication process for a semiconductor chip, especially for a chip to be integrated with a CMOS (Complementary Metal Oxide Semiconductor) device, a gold wire typically is substituted with a copper wire in chip packaging in order to lower fabrication cost of the chip. The chip typically includes a pad, which can be easily damaged during packaging and bonding in the pad area as the copper wire has a high hardness and is easy to be oxidized. Thus, metal layers in the pad area need to be thickened. As for a CMOS chip with a metal fuse, when necessary, a voltage needs to be applied to blow the metal fuse, so as to adjust a circuit structure in the chip. Therefore, windows need to be etched on a passivation layer to expose the metal fuse, to ensure that when the metal fuse is burned, the resultants can volatilize or flow out.

In the fabrication process for thickening the pad metal layers, the metal fuse can be easily damaged or etched off, and that can further change or destroy chip functions.

To avoid damaging the metal fuse while thickening the pad metal layers, the fabrication method for thickening the pad metal layers in the prior art mainly includes the following steps:

Referring to FIG. 1, a first metal layer 2, which is generally an aluminum (Al) layer, is grown on a silicon substrate 1.

Referring to FIG. 2, a metal wire comprising a metal fuse 22 and a pad 21 is etched on the first metal layer 2 using a photoetching and etching process.

Referring to FIG. 3, a medium layer 3, which is typically a silicon dioxide (SiO2) layer, is grown on the chip having the pad 21 and the metal fuse 22.

Referring to FIG. 4, only a window 23 of the pad area is etched on the medium layer 3 by using the photoetching and etching process, where this area is an area for copper wire bonding.

Referring to FIG. 5, a second metal layer 4 is fabricated on the chip having the window 23 of the pad area.

Referring to FIG. 6, the second metal layer 4 is etched to obtain a metal layer 41 covering the pad area, and the metal layer outside the pad area is completely etched off, and at this time, the partial first and second metal layers on the pad area are thickened pad metal layers.

Referring to FIG. 7, a passivation layer 5, which is silicon nitride, is grown on the chip.

Referring to FIG. 8, the passivation layer 5 is etched to expose the metal layer 41 of the pad area, and the medium layer 3 is then etched to expose the metal fuse 22 in a window of the metal fuse area.

In the above fabrication method for thickening pad metal layers, the medium layer is grown once and the passivation layer is grown once. The passivation layer and the medium layer are formed by sputtering two different materials. They need to be etched at different times when the window of the metal fuse area is formed. After the etching for the passivation layer is finished, etching parameters need to be changed for etching the medium layer. Therefore, the time for etching the two layers is long. Thus, this fabrication process for thickening pad metal layers is complex and expensive.

### SUMMARY OF THE INVENTION

Embodiments of the present invention provide a semiconductor chip with a metal fuse and a fabrication method for thickening pad metal layers thereof, in order to simplify the fabrication process for thickening the pad metal layers of the chip and lower the fabrication cost of the chip.

An embodiment of the present invention provides a fabrication method for thickening pad metal layers, comprising:

growing a first metal layer on a silicon substrate;

photoetching and etching the first metal layer to obtain a metal wire comprising a metal fuse and a pad;

growing a passivation layer on the metal wire;

photoetching and etching the passivation layer to obtain a first window exposing a pad area;

growing a second metal layer on the passivation layer having the first window;

photoetching and etching the second metal layer to obtain a metal layer covering the pad area and expose the passivation layer outside the pad area; and

photoetching and etching the passivation layer outside the pad area to obtain a second window exposing a metal fuse area.

An embodiment of the present invention provides a semiconductor chip, which is fabricated by the fabrication method above.

In the embodiment of the present invention, a first metal layer is grown on a silicon substrate; the first metal layer is photoetched and etched to obtain a metal wire comprising a metal fuse and a pad; a passivation layer is grown on the metal wire; the passivation layer is photoetched and etched to obtain a first window to expose a pad area; a second metal layer is grown on the passivation layer having the first window; the second metal layer is photoetched and etched to obtain a metal layer covering the pad area and expose the passivation layer outside the pad area; and the passivation layer outside the pad area is photoetched and etched to obtain a second window to expose a metal fuse area. In the process for thickening the pad metal layers, growth of the medium layer in the prior art is omitted, the fabrication process for thickening the pad metal layers of the chip is simplified, and the fabrication cost of the chip is lowered.

### BRIEF DESCRIPTION OF THE DRAWINGS

FIG. 1 is a cross-section diagram of a semiconductor chip in which a first metal layer in grown on a silicon substrate in the prior art;

FIG. 2 is a cross-section diagram of the chip having a metal wire in the prior art;

FIG. 3 is a cross-section diagram of the semiconductor chip having a medium layer in the prior art;

FIG. 4 is a cross-section diagram of the semiconductor chip having a window of a pad area in the prior art;

FIG. 5 is a cross-section diagram of the semiconductor chip having a second metal layer in the prior art;

FIG. 6 is a cross-section diagram of the semiconductor chip having a thickened window of the pad area in the prior art;

FIG. 7 is a cross-section diagram of the semiconductor chip having a passivation layer in the prior art;

FIG. 8 is a cross-section diagram of the semiconductor chip having a metal fuse window and the window of the pad area in the prior art;

FIG. 9 is a flow chart of a fabrication method for thickening a pad metal layer in accordance with an embodiment of the present invention;

FIG. 10 is a cross-section diagram of a semiconductor chip in which a first metal layer is grown on a silicon substrate in accordance with an embodiment of the present invention;

FIG. 11 is a cross-section diagram of the semiconductor chip having a metal fuse and a metal wire in accordance with an embodiment of the present invention;

FIG. 12 is a cross-section diagram of the semiconductor chip in which a passivation layer is grown in accordance with an embodiment of the present invention;

FIG. 13 is a cross-section diagram of the semiconductor chip with a first window exposing a pad area in accordance with an embodiment of the present invention;

FIG. 14 is a cross-section diagram of the semiconductor chip having a second metal layer in accordance with an embodiment of the present invention;

FIG. 15 is a cross-section diagram of the semiconductor chip having a thickened pad metal layer in accordance with an embodiment of the present invention; and

FIG. 16 is a cross-section diagram of the semiconductor chip with the metal fuse exposed and the thickened pad metal layer in accordance with an embodiment of the present invention.

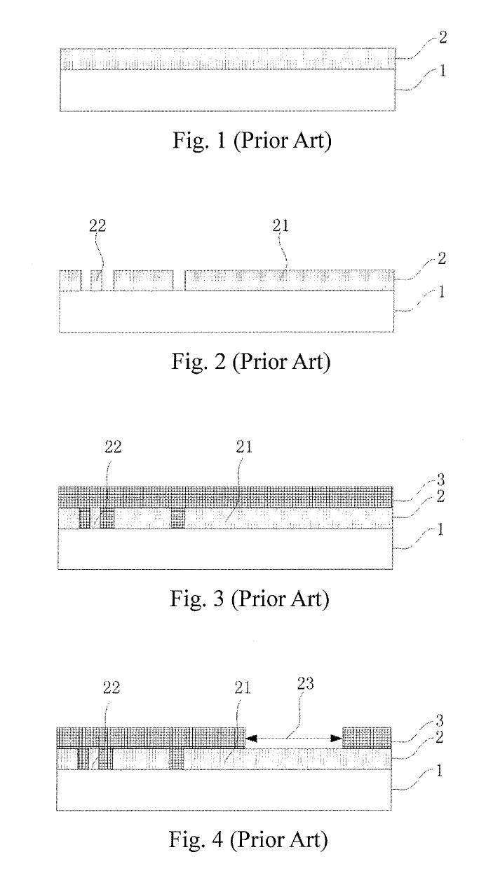

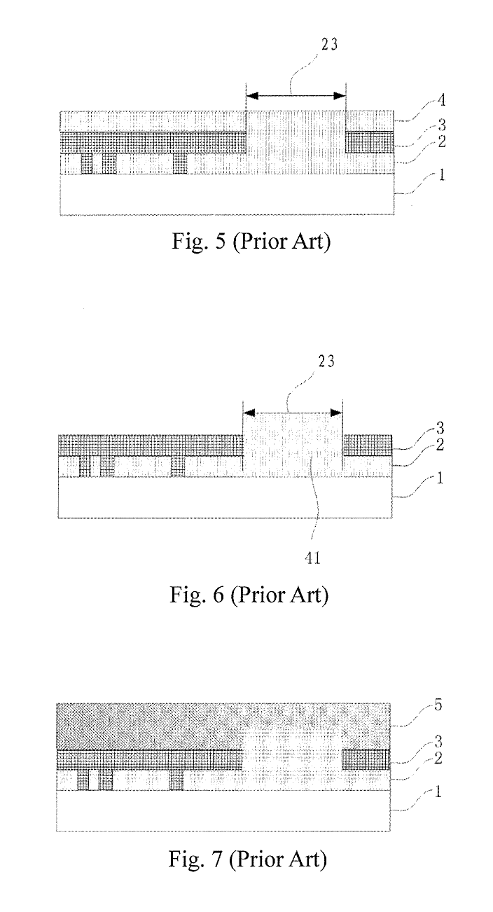

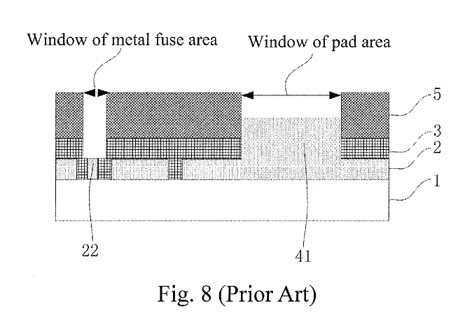

### DETAILED DESCRIPTION OF THE EMBODIMENTS

Embodiments of the present invention provide a semiconductor chip with a metal fuse and a fabrication method for thickening a pad metal layer thereof, in order to simplify the fabrication process for thickening the pad metal layer of the chip and lower the fabrication cost of the chip.

In an embodiment of the present invention, a window for a pad metal layer area is etched by growing a passivation layer on a first metal layer having a metal fuse and a metal wire. The pad metal layer area is thickened by growing a second metal layer on top of the pad metal layer. The second metal layer is etched to obtain a metal layer covering the pad metal layer area. The second metal layer outside the pad metal layer area can be etched off to expose the passivation layer. The passivation layer can be etched to expose the metal fuse. In the above fabrication method for thickening the pad metal layer, the metal fuse is protected from being damaged. Furthermore, there is no need for forming a medium layer, thus simplifying the fabrication process for thickening the pad metal layer and lowering the cost.

Technical solutions provided in the embodiments of the invention will be described below in detail with reference to the accompanying drawings.

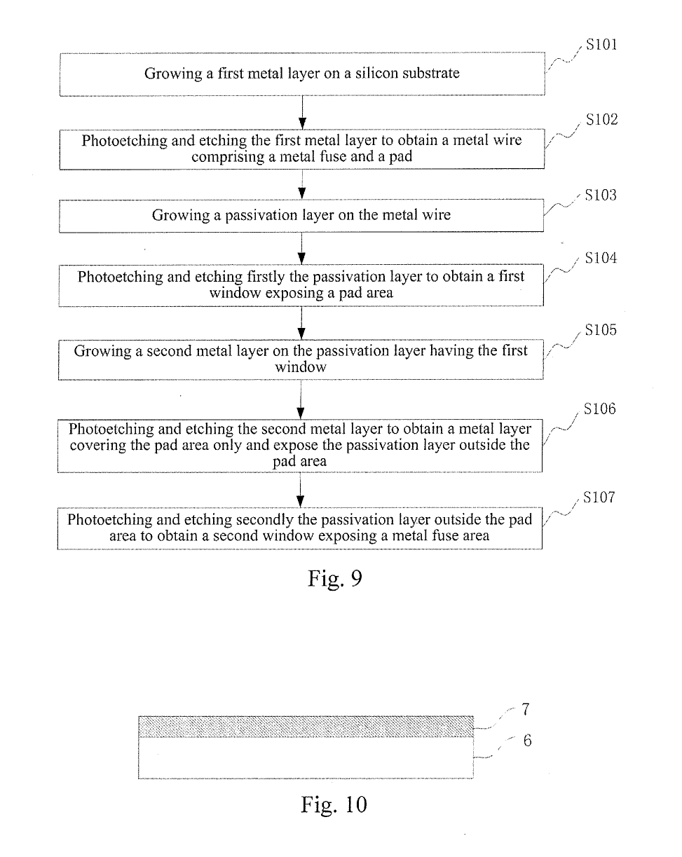

Referring to FIG. 9, an embodiment of the present invention provides a fabrication method for thickening a pad metal layer, comprising the following steps:

S101. growing a first metal layer on a silicon substrate.

S102. photoetching and etching the first metal layer to obtain a metal wire comprising a metal fuse and a pad.

S103. growing a passivation layer on the metal wire.

S104. photoetching and etching the passivation layer to obtain a first window exposing a pad area.

S105. growing a second metal layer on the passivation layer having the first window.

S106. photoetching and etching the second metal layer to obtain a metal layer covering the pad area and expose the passivation layer outside the pad area.

S107. photoetching and etching the passivation layer outside the pad area to obtain a second window exposing a metal fuse area.

The technical solutions provided in the embodiments of the invention will be explained below with reference to the accompanying drawings.

An embodiment of the present invention provides a fabrication method for thickening a pad metal layer. The method includes:

Referring to FIG. 10, a metal layer 7, which is about 1 μm thick, is grown on a polysilicon semiconductor substrate 6 by means of an ion sputtering method, and serves as a first metal layer 7. The first metal layer 7 may be Al—Si—Cu alloy with the content of aluminum reaching as high as 98.5% and is used for fabricating a metal wire comprising a metal fuse and a pad of a semiconductor chip.

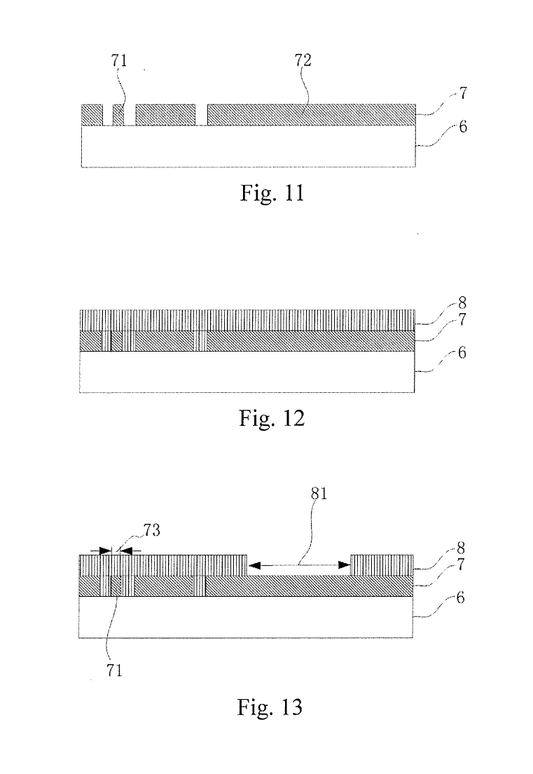

Referring to FIG. 11, the metal layer comprising the metal fuse 71 and the pad 72 is etched using a photoetching and etching processes, and the etching may be dry process etching.

Referring to FIG. 12, a passivation layer 8, which is about 0.9 μm thick, is deposited on the metal layer by means of a CVD (Chemical Vapor Deposition) method and serves as an insulating layer. The passivation layer 8 may be a silicon nitride (Si₃N₄) layer or an overlaying layer of SiO₂ and Si₃N₄, wherein Si₃N₄ is deposited at the outmost layer. The passivation layer 8 is used for protecting the metal wire and the metal fuse on chip from external damages and also for, in the process of thickening the pad metal layer, protecting the metal fuse from liquid corrosion during wet etching.

Referring to FIG. 13, the passivation layer 8 is etched using the photoetching and etching process to obtain a first window 81 to expose the pad area. The passivation layer of the window 81 of the pad area, when etched, needs to be etched completely in order to facilitate subsequent packaging and wire bonding. The etching is dry process etching. The passivation layer 73 above the fuse area is not etched in the process of etching the passivation layer 8.

Referring to FIG. 14, a metal layer 9 is grown on the passivation layer 8 by means of the ion sputtering method and serves as a second metal layer. The second metal layer 9 and the first metal layer 7 are made of the same material, which is Al—Si—Cu alloy with the content of aluminum reaching as high as 98.5% and is used for thickening the metal layer of the pad area, so that a copper wire does not puncture or damage the metal layer to further damage the chip during packaging and wire bonding in this area. The thickness of the second metal layer 9 is associated with the thickness of the copper wire and the thickness of the first metal layer 7, and generally, the damage to the metal layer of the pad area can be avoided if the total thickness h of the first metal layer 7 and the second metal layer 9 of the pad area is larger than or equal to 1.5 μm. However, a high thickness h of the metal layer of the pad area is unnecessary, so as to avoid increasing the fabrication cost of the chip.

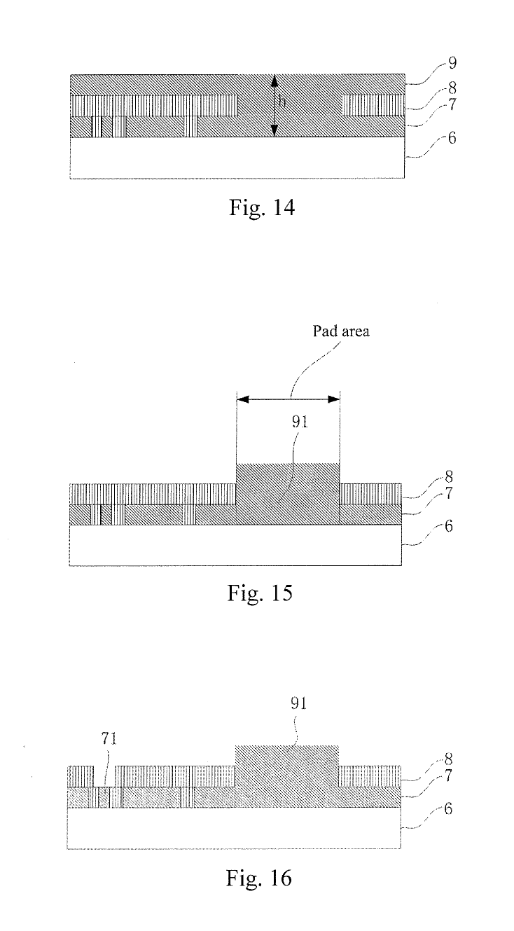

Referring to FIG. 15, the second metal layer 9 is photoetched and etched, the second metal layer outside the pad area above the passivation layer 8 is etched off by a wet etching process so as to expose the passivation layer 8 outside the pad area, and numeral 91 indicates the thickened pad metal layer.

Referring to FIG. 16, the passivation layer 8 is photoetched and etched by a dry etching process to obtain a window of the metal fuse area and expose the metal fuse 71, so that resultants of the metal fuse can volatilize or flow out of the chip while the metal fuse 71 is burned. The window of the metal fuse area is square or rectangular, and is sized to guarantee not only full exposure of the metal fuse, but also no exposure of other metal wires, so that resultants totally volatilize or flow out when the metal fuse is burned.

In the above fabrication process of thickening the pad metal layers, the photoetching and etching process is performed four times, wherein the first photoetching and etching is performed on the first metal layer to obtain the metal wire; the second photoetching and etching is performed on the passivation layer to obtain the first window to expose the pad area; the third photoetching and etching is performed on the second metal layer to expose the passivation layer outside the pad area; the fourth photoetching and etching is performed on the passivation layer to expose the metal fuse; the first, second and fourth etchings are all dry etching to ensure etching accuracy; the third etching is wet etching to save cost; in the second and fourth etchings, membrane layers etched are both the passivation layer, and etching parameters are completely consistent without changing the etching process or developing a new one, so that the fabrication process for thickening the pad metal layers is simplified and the fabrication cost is lowered.

Compared with the prior art, the present invention has the advantages of omitting a step of growing a medium layer and a step of photoetching and etching the medium layer, simplifying the fabrication process for thickening the pad metal layers and lowering the fabrication cost. This is because fabrication of the medium layer requires an extremely strict fabrication process, and the medium layer is formed by sputtering silicon dioxide of which the compactness is much lower than the compactness of the passivation layer. The acid can pass through the medium layer with poor compactness and corrodes the metal wire below the medium layer when wet process etching is performed on the second metal layer. In addition, the etching process parameters for the medium layer and for the passivation layer are different, which increases the complexity of the etching process.

In conclusion, the embodiment of the present invention provides a fabrication method for thickening pad metal layers, the method comprising: growing a first metal layer on a silicon substrate; photoetching and etching the first metal layer to obtain a metal wire comprising a metal fuse and a pad; growing a passivation layer on the metal wire; photoetching and etching the passivation layer to obtain a first window to expose a pad area; growing a second metal layer on the passivation layer having the first window; photoetching and etching the second metal layer to obtain a metal layer covering the pad area and expose the passivation layer outside the pad area; and photoetching and etching the passivation layer outside the pad area to obtain a second window to expose a metal fuse area. In the process for thickening the pad metal layer, growth of the medium layer in the prior art is omitted, the fabrication process for thickening the pad metal layer of the chip is simplified, and the fabrication cost of the chip is lowered.

Apparently, various modifications and variations of the present invention could be made by those skilled in the art without departing from the spirit and scope of the present invention. Thus, the present invention is also intended to encompass these modifications and variations thereto so long as these modifications and variations made to the present invention come into the scope of the claims of the present invention and equivalent techniques thereof.

1. A fabrication method for thickening a pad metal layer, comprising:
growing a first metal layer on a silicon substrate;
etching the first metal layer to obtain a metal wire comprising a metal fuse and a pad;
growing a passivation layer on the metal wire;
etching the passivation layer to obtain a first window to expose a pad area;
growing a second metal layer on the passivation layer having the first window;
etching the second metal layer to obtain a metal layer covering the pad area and expose the passivation layer outside the pad area;
and etching the passivation layer outside the pad area to obtain a second window to expose a metal fuse area.

2. The method according to claim 1, wherein parameters in the first etching and in the second etching for the passivation layer are the same.

3. The method according to claim 2, wherein the metal layer of the pad area has a total thickness of at least 1.5 μm.

4. The method according to claim 1, wherein the first and second metal layers are made of the same material.

5. The method according to claim 1, wherein at least one of the first metal layer or the second metal layer is made from an Al—Si—Cu alloy.

6. The method according to claim 1, wherein the second metal layer is etched by a wet etching process, and the passivation layer and the first metal layer are etched by a dry etching process.

7. (canceled)

8. A method for making a pad metal layer, comprising:
forming a first metal layer on a silicon substrate;
etching the first metal layer to obtain a metal fuse and a pad on the silicon substrate;
forming a passivation layer directly on the first metal layer;
etching the passivation layer to obtain a first window to expose a pad area;
forming a second metal layer on the passivation layer;
etching the second metal layer to obtain a metal layer covering the pad area and expose the passivation layer outside the pad area;
and etching the passivation layer to obtain a second window to expose the metal fuse.

9. The method according to claim 8, wherein the first metal layer and the second metal layer at the pad area have a total thickness of at least 1.5 μm.

10. The method according to claim 8, wherein the first and second metal layers are made of the same material.

11. The method according to claim 8, wherein at least one of the first metal layer or the second metal layer is made from an Al—Si—Cu alloy.

12. The method according to claim 8, wherein etching the second metal layer includes etching the second metal layer with a wet etching process.

13. The method according to claim 8, wherein etching the first metal layer includes etching the first metal layer with a dry etching process.

14. The method according to claim 8, wherein etching the passivation layer to obtain a first window includes etching the passivation layer with a dry etching process.

15. A semiconductor device comprising:
a substrate;
a first metal layer including a metal fuse and a metal pad on the substrate;
a passivation layer directly deposited on the first metal layer, wherein the passivation layer includes openings for exposing the metal fuse and the metal pad respectively;
and a second metal layer on the metal pad.

16. The semiconductor device according to claim 15, wherein the first metal layer and the second metal layer have a total thickness of at least 1.5 μm.

17. The semiconductor device according to claim 15, wherein the first and second metal layers are made of the same material.

18. The semiconductor device according to claim 15, wherein at least one of the first metal layer or the second metal layer is made from an Al—Si—Cu alloy.
